(19) United States
(12) Patent Application Publication
(10) Pub. No.: US 2002/0016063 A1
(43) Pub. Date: Feb. 7, 2002

(54) METHOD OF FABRICATING A METAL PLUG OF A SEMICONDUCTOR DEVICE USING A NOVEL TIN BARRIER LAYER

(76) Inventors: MING-SHING CHEN, KAOHSIUNG HSIEN (TW); BILL HSU, HSINCHU HSIEN (TW)

Correspondence Address: J.C. PATENTS INC., 4 VENTURE, SUITE 250, IRVINE, CA, 92618, US

(21) Appl. No.: 09/322,054

(22) Filed: May 27, 1999

(30) Foreign Application Priority Data
Apr. 7, 1999 (TW) 88105508

(51) Int. Cl. H01L 21/44; H01L 21/4763

(52) U.S. Cl. 438/653; 438/631; 438/643; 438/645; 438/627

(57) ABSTRACT

A method of fabricating a metal plug comprises steps of providing a substrate and forming a dielectric layer on the substrate with an opening to expose part of the substrate. The method further comprises steps of forming a metal layer on the dielectric layer, forming a first barrier layer by chemical vapor deposition (CVD) to provide a better step coverage, and forming a second barrier layer by physical vapor deposition (PVD) to make the barrier layer harder and less water absorptive. A metal layer is then formed on the second barrier layer and is removed by etching back to form the metal plug.

### BACKGROUND OF THE INVENTION

1. Field of Invention

The present invention relates to a method of fabricating a semiconductor device. More particularly, the present invention relates to a method of fabricating a metal plug.

2. Description of Related Art

Conventionally, in the manufacture of a metal plug, a barrier layer is deposited to improve the adhesion between a metal layer and a dielectric layer. The barrier layer such as a TiNₓ layer is usually deposited by chemical vapor deposition (CVD) to provide a better step coverage. Following the deposition of the barrier layer, a metal layer is deposited to form a metal plug.

FIGS. 1A to 1D are diagrams that illustrate a conventional structure of a metal plug.

Referring to FIG. 1A, a substrate 100 is provided with a dielectric layer 101 formed thereon. The substrate 100 typically comprises a conducting region such as a metal layer or a metal oxide semiconductor device (MOS device) which further comprises a gate and a source/drain region (not shown). The dielectric layer 101 is patterned and a part of the dielectric layer 101 is removed until the substrate 100 is exposed. As a result, an opening 102 is formed in the dielectric layer 101.

Referring to FIG. 1B, a conformal titanium (Ti) layer 104 is formed over the substrate 100. Using chemical vapor deposition (CVD), a titanium nitride layer 106 is formed on the titanium layer 104.

Referring to FIG. 1C, a tungsten layer 108 is formed on the titanium nitride layer 106 to fill the opening 102.

In FIG. 1D, the tungsten layer 108 is etched until the titanium nitride 106 is exposed, consequently, a tungsten plug is formed in the opening 102.

In the conventional method mentioned as above, the texture of the titanium nitride layer 106 used as a barrier layer is soft and has a tendency to absorb water, so that the titanium nitride layer 106 is not suitable to experience a cleaning or spray step after being deposited. However, without performing a cleaning or spray step, particle issue is likely to remain on the titanium nitride layer 106. Therefore, the titanium nitride layer 106 can only be preserved for a certain period of time. As a consequence, the reliability of devices is serious affected. Moreover, the texture of the titanium nitride layer 106 formed by chemical vapor deposition is loose. While etching back the tungsten layer 108, the etching rate of the titanium nitride layer 106 is much faster than that of a titanium nitride layer formed by physical vapor deposition. It is thus that the etching back step is not suitable to perform on the tungsten layer 108. Instead, a chemical-mechanical polishing step is applied. Furthermore, in the step of etching back the tungsten layer 108, the titanium nitride layer has to be thickened to increase the process window. However, the RC delay time is consequently increased.

### SUMMARY OF THE INVENTION

Therefore, the present invention provides a method of fabricating a metal plug that is applicable to both tungsten etching back and CMP processes, so as to prevent the device from being damaged or poisoned.

A substrate is provided. A dielectric layer is formed on the substrate, followed by being patterned to form an opening exposing a part of the substrate. A conformal metal layer is formed to cover the dielectric layer and the exposed substrate in the opening, while a first barrier layer is deposited by CVD on the metal layer. A second barrier layer is deposited by PVD on the first barrier layer, while a metal layer is deposited on the second barrier layer.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A to 1D are cross-sectional diagrams showing the process flow of fabricating a conventional metal plug.

FIGS. 2A to 2E are cross-sectional diagrams showing the process flow of fabricating a metal plug according to a preferred embodiment of the invention.

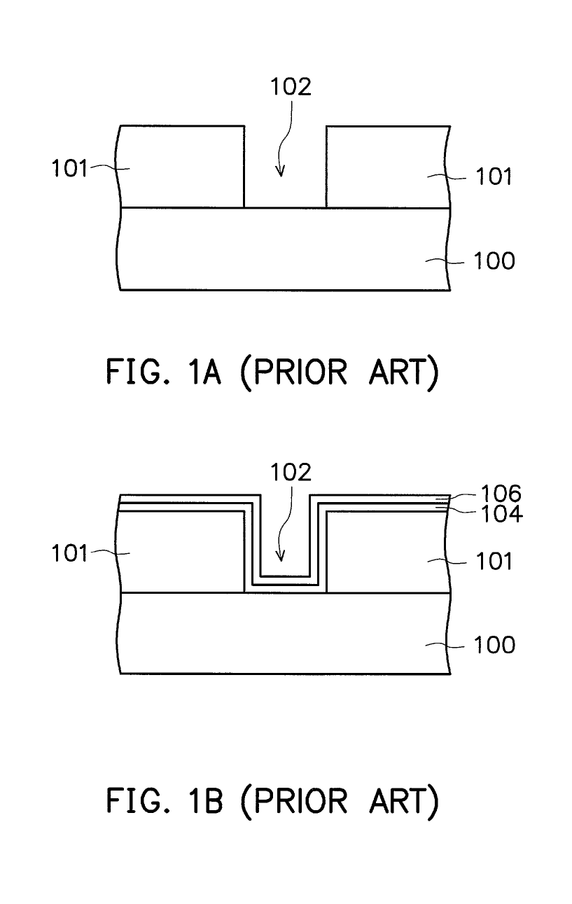

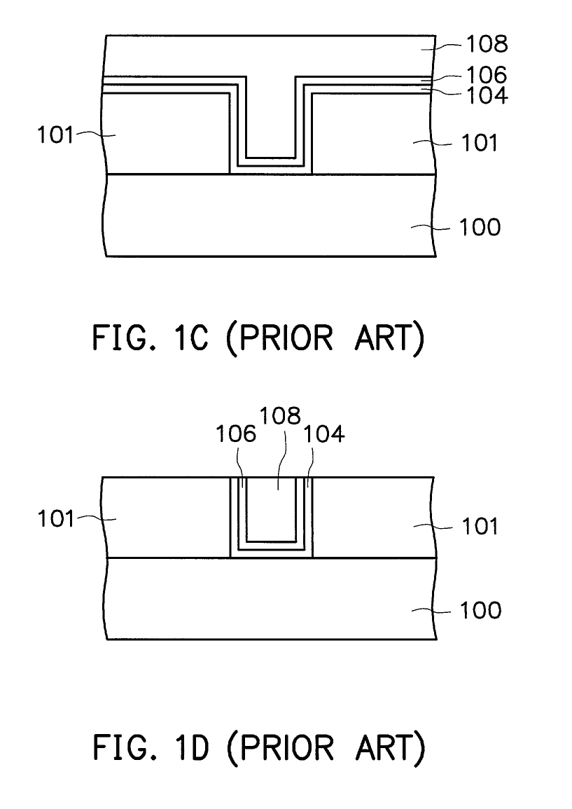

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

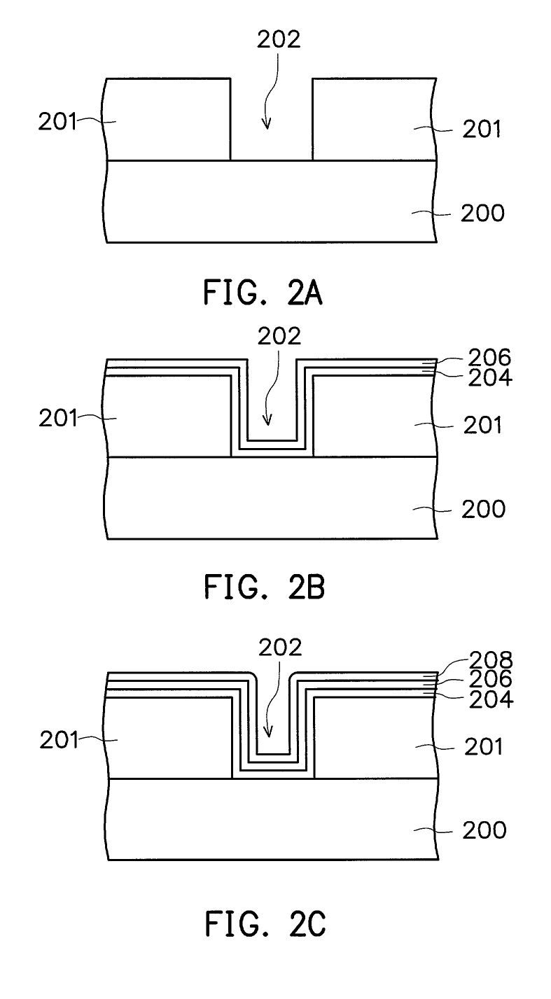

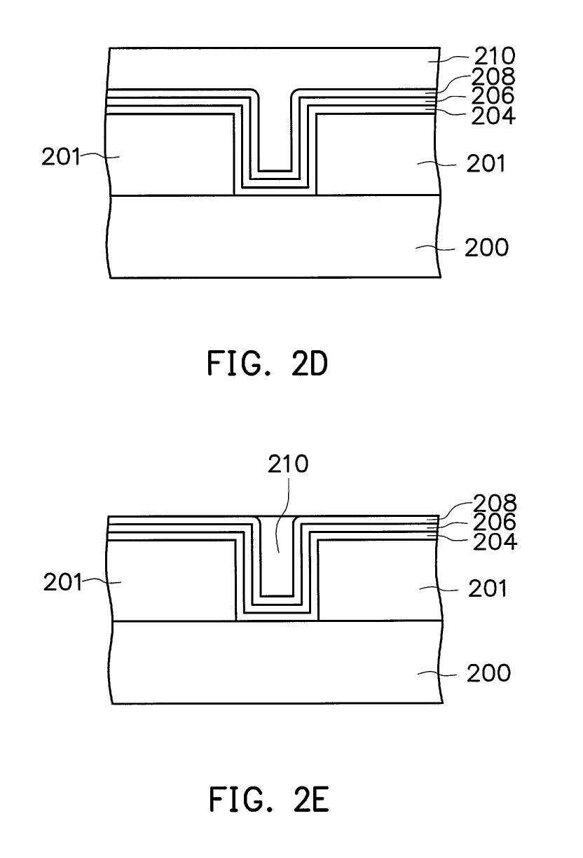

The embodiment of the present invention is described below with the reference to FIG. 2A through FIG. 2E.

Referring to FIG. 2A, a substrate 200 is provided with a dielectric layer 201 formed on the substrate 200. The substrate 200 may be connected to the conducting region such as a metal layer or a metal oxide semiconductor device (MOS device), such as a gate or source/drain region (not shown). The dielectric layer 201 is defined and a part of the dielectric layer 201 is removed until the substrate 200 is exposed, so that an opening 202 is formed in the dielectric layer 201. In this case, the material of the dielectric layer 201 may be silicon oxide (SiOₓ) while the opening 202 may be a contact window or via hole.

Referring to FIG. 2B, a metal layer 204 is formed, preferably a titanium layer formed by sputtering and physical vapor deposition (PVD), on the substrate 200. The metal layer is formed to reduce the contact resistance. A first barrier layer 206 is formed by chemical vapor deposition (CVD) on the metal layer 204. The first barrier layer 206 is formed of, for example, TiNₓ, to a thickness of about 75-100 Å. According to the invention, the first barrier layer 206 is deposited to provide a better step coverage on the dielectric layer 201.

Referring to FIG. 2C, a second barrier layer 208 is formed on the first barrier layer 206 by PVD. The second barrier layer 208 is formed preferably of TiNₓ to a thickness of about 15-200 Å. Since the second barrier layer 208 is formed by PVD, it is harder and less absorptive of water than the first barrier layer 206. So, a combination of the first barrier layer 206 and the second barrier layer 208 provides a better step coverage with enough hardness and less water absorption. As a result, there will be no poisoning effect during the subsequent metal layer deposition.

Referring to FIG. 2D, a metal layer 210 is formed on the second barrier layer 208 to fill the opening 202. The metal layer 210, such as tungsten layer, may be formed by a PVD or CVD to cover the second barrier layer 208.

Referring to FIG. 2E, the metal layer 210 is removed until the second barrier layer 208 is exposed, so as to form a metal plug. Since the second barrier layer 208 provides a sufficient hardness for the metal plug structure, the structure underneath the second barrier layer would not be damaged in the subsequent etching process. The metal layer 210 may be removed by etching or chemical mechanical polishing (CMP). However, it is preferably removed by tungsten etching back (WEB), as it is less costly to perform the etching process than to perform the CMP.

After the removal of the metal layer 210 by WEB or CMP, there may be some particles remaining on the second barrier layer 208. These particles are usually removed by brush cleaning or spray cleaning. According to the invention, the damage caused by etching as well as the poisoning effect experienced after the brush cleaning/ spray cleaning is thus prevented.

It is understood from the preferred embodiment described above that the invention has following advantages. The structure of the metal plug, which combines the first barrier layer with the second barrier layer, is not damaged easily and has no poisoning effect, while it provides good step coverage. This is because the first barrier layer deposited by CVD provides a better step coverage than that deposited by PVD, while the second barrier layer protects the device from damage by offering hardness and less water absorption during the etching and cleaning processes. As the second barrier layer is included to strengthen the metal plug structure, it is not necessary to perform an expensive CMP process to remove the metal layer to expose the second barrier layer. Thus, the cycle time and the cost of the whole process is greatly reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a semiconductor device, comprising steps of:
providing a substrate;
forming a dielectric layer with an opening on the substrate to expose part of the substrate;
forming a conformal metal layer on the dielectric layer and an exposed surface of the opening;
forming a first barrier layer on the metal layer;
forming a second barrier layer on the first barrier layer, wherein the second barrier layer has a denser structure and is less water absorptive compared to the first barrier; and
forming a metal plug to fill the opening.

2. The method of claim 1, wherein the metal layer includes a Ti layer.

3. The method of claim 1, wherein the two barrier layers comprise of a first barrier layer and a second barrier layer.

4. The method of claim 4, wherein the first barrier layer is formed by chemical vapor deposition (CVD) on the metal layer.

5. The method of claim 5, wherein the second barrier layer is formed by physical vapor deposition (PVD) on the first barrier layer.

6. The method of claim 1, wherein the metal plug is formed by the steps:
forming a metal layer on the second barrier layer to fill the opening; and
etching back the metal layer until the second barrier layer is exposed.

7. The method of claim 1, wherein the metal plug is formed by the steps:
forming a metal layer on the second barrier layer to fill the opening; and
performing a chemical-mechanical polishing step on the metal layer until the second barrier layer is exposed.

8. A method of fabricating a metal plug, comprising steps of:
providing a substrate;
forming a dielectric layer with an opening on the substrate to expose part of the substrate;
forming a metal layer on the dielectric layer and the exposed substrate;
forming a first barrier layer on the metal layer by chemical vapor deposition;
forming a second barrier layer on the first barrier layer by physical vapor deposition;
forming a metal layer on the second barrier layer to fill the opening; and
removing the metal layer until the second barrier layer is exposed to form the metal plug.

9. The method of claim 8, wherein the metal layer includes a Ti layer.

10. The method of claim 8, wherein the first barrier layer includes a TiNₓ layer.

11. The method of claim 10, wherein the first barrier layer is formed by CVD on the metal layer.

12. The method of claim 11, wherein the first barrier layer has a thickness of about 75-100 Å.

13. The method of claim 8, wherein the second barrier layer includes a TiNₓ layer.

14. The method of claim 13, wherein the second barrier layer is formed by PVD on the first barrier layer.

15. The method of the claim 14, wherein the second barrier layer has a thickness of about 150-200 Å.

16. The method of claim 8, wherein the metal layer includes tungsten layer.

17. The method of claim 16, wherein the tungsten layer is removed by tungsten etching back.
